(19) United States
(12) Patent Application Publication
(10) Pub. No.: US 2026/0107072 A1
(43) Pub. Date: Apr. 16, 2026

(54) IMAGE SIGNAL PROCESSOR

(71) Applicant: SK hynix Inc., Gyeonggi-do (KR)

(72) Inventors: Dong Ik KIM, Gyeonggi-do (KR); Cheol Jon JANG, Gyeonggi-do (KR); Jun Hyeok CHOI, Gyeonggi-do (KR)

(21) Appl. No.: 19/187,889

(22) Filed: Apr. 23, 2025

(30) Foreign Application Priority Data
Oct. 11, 2024 (KR) 10-2024-0138824

(51) Int. Cl. H04N 25/68; H04N 25/673

(52) U.S. Cl. CPC H04N 25/68; H04N 25/673

(57) ABSTRACT

An image signal processor capable of performing image conversion is disclosed. The image signal processor includes a defective pixel detector configured to determine whether a target pixel is a defective pixel based on pixel data of a reference pixel having the same attributes as the target pixel; and a defective pixel corrector configured to correct pixel data of the target pixel when it is determined that the target pixel is the defective pixel. The defective pixel detector corrects a luminance of the reference pixel using a luminance deviation between target neighbor pixels adjacent to the target pixel and reference neighbor pixels adjacent to the reference pixel; compares a threshold value with a difference value obtained based on the pixel data of the target pixel and correction data of the reference pixel; and determines whether the target pixel is the defective pixel based on a result of the comparison.

### CROSS-REFERENCE TO RELATED APPLICATION

This patent application claims the priority and benefits of Korean patent application No. 10-2024-0138824, filed on Oct. 11, 2024, which is incorporated herein by reference in its entirety.

### TECHNICAL FIELD

The technology and embodiments disclosed in the present disclosure generally relate to an image signal processor capable of performing image conversion.

### BACKGROUND

An image sensing device captures optical images by converting light into electrical signals using a photosensitive semiconductor material which reacts to light. With the development of automotive, medical, computer and communication industries, the demand for high-performance image sensing devices is increasing in various fields such as smartphones, digital cameras, game machines, Internet of Things (IoT), robots, surveillance cameras and medical micro cameras.

An original image photographed by the image sensing device may include an original defect or an image of defective pixels that do not correspond to a normal image due to temporary factors. Since the image of these defective pixels causes deterioration of the quality of the image, a process of correcting the image of the defective pixels is required. The positions of the defective pixels may be randomly changed, and the quality of the image may be improved as the detection accuracy of the defective pixels increases.

### SUMMARY

Various embodiments of the present disclosure relate to an image signal processor that can more correctly detect defective pixels in the edge region of an image, and an image signal processing method for the same.

In accordance with an embodiment of the present disclosure, an image signal processor may include a defective pixel detector configured to determine whether a target pixel is a defective pixel based on pixel data of a reference pixel having the same attributes as the target pixel; and a defective pixel corrector configured to correct pixel data of the target pixel when it is determined that the target pixel is the defective pixel. The defective pixel detector may correct a luminance of the reference pixel using a luminance deviation between target neighbor pixels adjacent to the target pixel and reference neighbor pixels adjacent to the reference pixel; may compare a threshold value with a difference value obtained based on the pixel data of the target pixel and correction data of the reference pixel; and may determine whether or not the target pixel is the defective pixel based on a result of the comparison.

In accordance with another embodiment of the present disclosure, an image signal processor may include a threshold calculator configured to calculate a threshold value for a target pixel included in a target kernel based on kernel type information and complexity of the target kernel; and a defective pixel determiner configured to determine whether the target pixel is a defective pixel based on pixel data of a reference pixel having the same attributes as the target pixel. The defective pixel determiner may be configured to correct a luminance of the reference pixel using a luminance deviation between target neighbor pixels adjacent to the target pixel and reference neighbor pixels adjacent to the reference pixel; compare the threshold value with a difference value obtained based on the pixel data of the target pixel with correction data of the reference pixel; and determine whether the target pixel is the defective pixel based on a result of the comparison.

It is to be understood that both the foregoing general description and the following detailed description of the embodiments of the present disclosure are illustrative and descriptive and are intended to provide further description of the embodiments as claimed.

### BRIEF DESCRIPTION OF THE DRAWINGS

The above and other features and beneficial aspects of the embodiments of the present disclosure will become readily apparent with reference to the following detailed description when considered in conjunction with the accompanying drawings.

FIG. 1 is a block diagram illustrating an image signal processor based on some embodiments of the present disclosure.

FIG. 2 is a block diagram illustrating a defective pixel detector shown in FIG. 1 based on some embodiments of the present disclosure.

FIG. 3 is a flowchart illustrating operations of the image signal processor when a target kernel is a pattern kernel based on some embodiments of the present disclosure.

FIG. 4 is a flowchart illustrating operations of the image signal processor when a target kernel is a flat kernel based on some embodiments of the present disclosure.

FIGS. 5 and 6 are schematic diagrams illustrating target kernels based on some embodiments of the present disclosure.

FIG. 7 is a block diagram illustrating a computing device corresponding to the image signal processor of FIG. 1 based on some embodiments of the present disclosure.

### DETAILED DESCRIPTION

The present disclosure provides embodiments and examples of an image signal processor capable of performing image conversion that may be used in configurations to substantially address one or more technical or engineering issues and to mitigate limitations or disadvantages encountered in some image signal processors in the art. Some embodiments of the present disclosure relate to an image signal processor that can more correctly detect defective pixels in the edge region of an image. In recognition of the issues above, the image signal processor based on some embodiments of the present disclosure can more correctly detect the defective pixels in the edge region of an image.

Reference will now be made in detail to some embodiments of the present disclosure, examples of which are illustrated in the accompanying drawings. Wherever possible, the same reference numbers will be used throughout the drawings to refer to the same or like parts. While the embodiments are susceptible to various modifications and alternative forms, specific embodiments thereof are shown by way of example in the drawings. However, the present disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of advantageous effects capable of being directly or indirectly recognized.

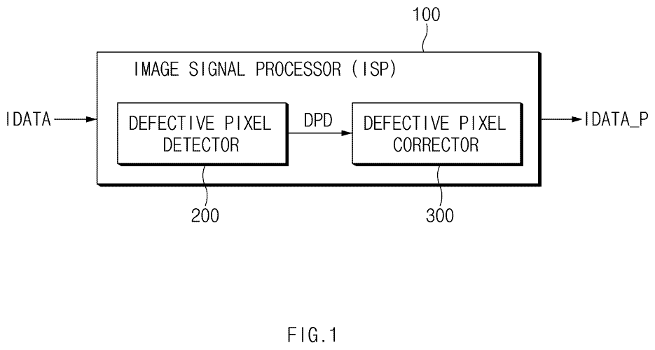

FIG. 1 is a block diagram illustrating an image signal processor (ISP) 100 based on some embodiments of the present disclosure.

Referring to FIG. 1, the image signal processor (ISP) 100 may perform at least one image signal process on image data (IDATA) to generate the processed image data (IDATA_P).

The image signal processor 100 may reduce noise of image data (IDATA), and may perform various kinds of image signal processing for image-quality improvement of the image data. Non-limiting examples of image signal processing may include demosaicing, defect pixel correction, gamma correction, color filter array interpolation, color matrix, color correction, color enhancement, lens distortion correction, etc.

The image signal processor 100 may compress image data that has been created by execution of image signal processing for image-quality improvement, such that the image signal processor 100 can create an image file using the compressed image data. Alternatively, the image signal processor 100 may recover image data from the image file. In some embodiments, the scheme for compressing such image data may be a reversible format or an irreversible format. As a representative example of such compression format, in the case of using a still image, Joint Photographic Experts Group (JPEG) format, JPEG 2000 format, or the like can be used. In the case of using moving images, a plurality of frames can be compressed according to Moving Picture Experts Group (MPEG) standards such that moving image files can be created.

The image data (IDATA) may be generated by an image sensing device that captures an optical image of a scene, but the scope of the present disclosure is not limited thereto. The image sensing device may include a pixel array including a plurality of pixels configured to detect incident light received from a scene, a control circuit configured to control the pixel array, and a readout circuit configured to output digital image data (IDATA) by converting an analog pixel signal received from the pixel array into the digital image data (IDATA). In some embodiments of the present disclosure, the image data (IDATA) is generated by the image sensing device.

The pixel array may include a color filter array (CFA) in which color filters are arranged according to a predetermined pattern (e.g., a Bayer pattern, a quad-Bayer pattern, a nona-Bayer pattern, an RGBW pattern, etc.) so that each color filter can sense light of a predetermined wavelength band. The pattern of the image data (IDATA) may be determined according to the type of the pattern of the CFA. The word “predetermined” as used herein with respect to a parameter, such as a predetermined pattern, threshold, size, distance, condition, algorithm, and wavelength band, means that a value of the parameter is determined prior to the parameter being used in a process or algorithm. In some embodiments, the value of the parameter is determined before the process or algorithm begins. In other embodiments, the value of the parameter is determined during the process or during execution of the algorithm but before the parameter is used in the process or algorithm.

The image signal processor (ISP) 100 may include a defective pixel detector 200 and a defective pixel corrector 300.

The defective pixel detector 200 may detect a defective pixel using image data (IDATA). The defective pixel detector 200 may detect a defective pixel, and may output defective pixel information (DPD) to the defective pixel corrector 300.

The defective pixel may refer to a pixel that does not normally generate pixel data corresponding to the intensity of incident light. The defective pixel may be a predetermined fixed defective pixel (e.g., a phase-difference detection autofocus (PDAF) pixel, a defective pixel having a defect due to manufacturing process limitations) according to pixel attributes, or may be a defective pixel which cannot generate normal pixel data temporarily due to environmental or structural causes. The PDAF pixel may be a pixel for obtaining phase difference information to implement an autofocus function, and may be classified as a defective pixel from the viewpoint of image data processing.

The defective pixel detector 200 may detect position information of a defective pixel from image data (IDATA). The defective pixel detector 200 may detect pixel data of a defective pixel from image data (IDATA). Digital data corresponding to a pixel signal of each pixel will hereinafter be defined as pixel data, and a set (aggregate) of pixel data corresponding to a predetermined unit (e.g., a frame or kernel) will hereinafter be defined as image data (IDATA). The frame may correspond to the entire pixel array, and the kernel may refer to a unit for image signal processing. In the present embodiments, if pixels are included in a kernel, this may mean an example case in which the corresponding pixels are arranged to correspond to the kernel corresponding to a specific operation unit.

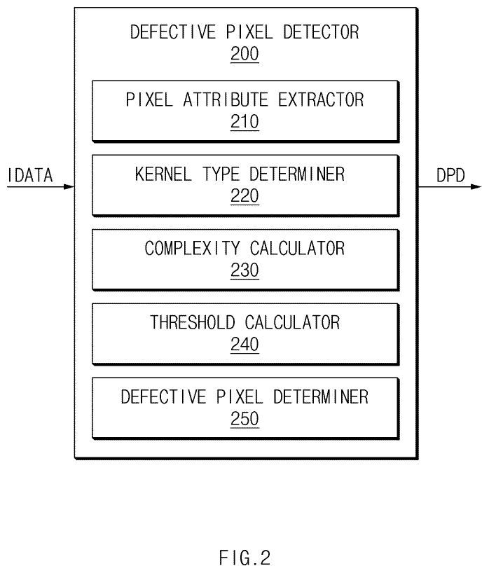

The defective pixel detector 200 may receive pre-stored position information of defective pixels from the image sensing device that generates image data (IDATA), and may determine whether the target pixel is a defective pixel based on the position information of the defective pixels. The image sensing device may store position information of fixed defective pixels due to fabrication process reasons in an internal storage (e.g., one time programmable (OTP) memory), and may provide the position information of the defective pixels to the image signal processor 100. More detailed operations of the defective pixel detector 200 will be described later with reference to FIG. 2.

When the target pixel is determined to be a defective pixel by the defective pixel detector 200, the defective pixel corrector 300 may correct pixel data of the target pixel based on image data of a kernel including the target pixel. The pixel data of the target pixel may mean normal color pixel data that can be obtained if the target pixel is not a defective pixel.

In one embodiment, the defective pixel corrector 300 may correct the pixel data of the target pixel using the pixel data of pixels that have the same attribute as the target pixel from among the pixels included in the kernel. In another example, the defective pixel corrector 300 may perform defective pixel correction in units of a mask having a predetermined size. In this case, the defective pixel correction may include an operation of calculating (e.g., linearly interpolating) pixel data of at least one pixel that is the same type (homogeneous) as (and/or a different type (heterogeneous) from) a target pixel within a mask structured such that the target pixel to be corrected is located at a center of the mask, and then obtaining pixel data corresponding to the target pixel.

FIG. 2 is a block diagram illustrating the defective pixel detector 200 shown in FIG. 1 based on some embodiments of the present disclosure.

Referring to FIG. 2, the defective pixel detector 200 may include a pixel attribute extractor 210, a kernel type determiner 220, a complexity calculator 230, a threshold calculator 240, and a defective pixel determiner 250.

The pixel attribute extractor 210 may extract (or obtain) attribute information of a pixel corresponding to pixel data included in the image data (IDATA). The pixel attribute extractor 210 may provide attribute information of pixels required to operate other components 220 to 250 of the defective pixel detector 200.

In some embodiments, the attribute information of the pixel may include at least one of color information (e.g., red, green, and/or blue) of the corresponding pixel, information on whether the corresponding pixel is a fixed defective pixel (e.g., a PDAF pixel or a poor pixel), and information about the position of the corresponding pixel. In one embodiment, the pixel attribute extractor 210 may extract attribute information of the defective pixel. The attribute information of the pixel may be stored for each pixel in a memory (for example, a line memory or a frame memory) that can be accessed by the image signal processor (ISP) 100.

The kernel type determiner 220 may receive the image data (IDATA), and may determine whether a target kernel including a target pixel is a flat kernel or a pattern kernel. The target kernel may correspond to a target kernel for determining a flat kernel or a pattern kernel among a set of pixel data of a predetermined unit including pixel data of the target pixel. In one embodiment, the kernel type determiner 220 may be classified into a flat kernel determiner or a pattern kernel determiner.

The kernel type determiner 220 may analyze a texture for each kernel based on image data (IDATA). Image data (IDATA) corresponding to one frame may include textures of various sizes and shapes. The texture refers to a set (aggregate) of pixels having similarity, and for example, a subject (target object) having a uniform color included in a scene may be recognized as a texture. The texture may be one of the characteristics indicating whether the target kernel is a flat kernel or a pattern kernel including an edge (or corner) region. In some embodiments, a flat kernel may refer to a region in which the target kernel does not have specific directivity and has very similar pixel data overall, and may refer to a texture region that is simpler than an edge region. A boundary of the texture may be defined as an edge, and the edge region may refer to a region including any of a horizontal edge, a vertical edge, or a diagonal edge. A difference between pixel data inside a texture and pixel data outside a texture may be greater than a difference between normal pixel data.

The kernel type determiner 220 may determine the target kernel to be a flat kernel when the target kernel does not correspond to a certain pattern shape. For example, the kernel type determiner 220 may determine the target kernel to be a flat kernel when a standard deviation of pixel data of each pixel included in the target kernel is less than a set value (i.e., a preset value). The set value may correspond to a value stored in advance in the image signal processor 100 to determine the type of the kernel.

In one embodiment, the kernel type determiner 220 may determine the target kernel to be a pattern kernel when the target kernel corresponds to a certain pattern shape such as a corner pattern or an edge pattern. For example, the kernel type determiner 220 may determine the target kernel to be a pattern kernel when a standard deviation of pixel data of each pixel included in the target kernel is greater than or equal to a set value.

The kernel type determiner 220 may transmit kernel type information of the target kernel to the threshold calculator 240. For example, the kernel type determiner 220 may transmit, to the threshold calculator 240, kernel type information indicating whether the kernel type of the target kernel is a flat kernel type or a pattern kernel type.

The complexity calculator 230 may calculate complexity of a target kernel including a target pixel. The complexity may refer to mean deviation, and may be an average index indicating how much pixel data of each pixel is scattered (distributed) from the average value of pixel data of pixels included in the target kernel.

The threshold calculator 240 may receive kernel type information, and may calculate a threshold value, which is a reference value for detecting defective pixels. In one embodiment, the threshold calculator 240 may calculate the threshold value in different ways based on a kernel type of the target kernel.

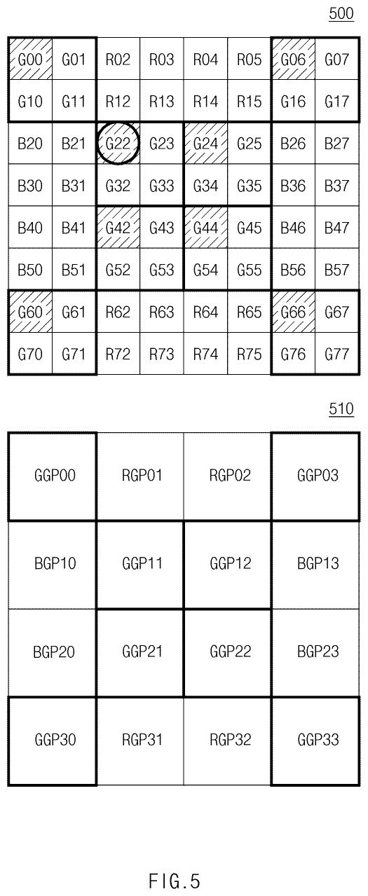

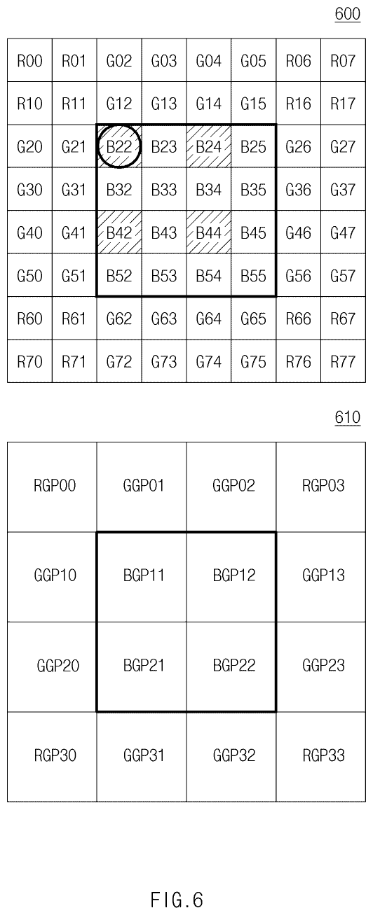

When the target kernel is determined to be the flat kernel, the threshold calculator 240 may calculate a threshold value based on pixel data of each pixel that corresponds to a color filter of the same color as the target pixel and/or is located at the same channel. For example, the threshold calculator 240 may determine, as a threshold value, a specific value corresponding to a standard deviation of pixel data of each pixel that corresponds to a color filter of the same color as the target pixel and/or is located at the same channel as the target pixel. In the present disclosure, pixels located at the same channel may refer to pixels having the same relative position from a center point of each microlens. A more detailed description of pixels located at the same channel will be described later with reference to FIGS. 5 and 6.

When the target kernel is determined to be a pattern kernel, the threshold calculator 240 may calculate a threshold value based on pixel data of each pixel that is included in the same pattern as the target pixel, corresponds to a color filter of the same color as the target pixel, and/or is located at the same channel as the target pixel. For example, when the target kernel is a corner pattern, the threshold calculator 240 may determine, as a threshold value, a specific value that is included in the same corner pattern as the target pixel, corresponds to a color filter having the same color as the target pixel, and corresponds to a standard deviation of pixel data of pixels included in the same channel as the target pixel.

The threshold calculator 240 may transmit, to the defective pixel determiner 250, threshold value information including the calculated threshold value. For example, the threshold calculator 240 may transmit, to the defective pixel determiner 250, threshold value information corresponding to the target kernel serving as a flat kernel, or threshold value information corresponding to the target kernel serving as a pattern kernel.

According to an embodiment, the threshold calculator 240 may determine the threshold value to be a fixed constant or may determine the threshold value to be a specific ratio of a luminance value (i.e., an average value of green color) of a current kernel. In one embodiment, the threshold calculator 240 may set the threshold value based on the standard deviation of pixels located within the target kernel. For example, the threshold calculator 240 may compare a standard deviation of pixel data of pixels located at the same channel within the target kernel with a standard deviation of pixel data of pixels located in the target kernel, and may determine a preset threshold value based on the result of such comparison.

The defective pixel determiner 250 may receive threshold value information, and may determine whether the target pixel is a defective pixel based on the threshold value information. In one embodiment, the defective pixel determiner 250 may correct luminance of a reference pixel by using a luminance deviation of neighbor pixels (hereinafter referred to as “target neighbor pixels”) of the target pixel and a luminance deviation of neighbor pixels (hereinafter referred to as “reference neighbor pixels”) of the reference pixel having the same color as the target pixel. The term “neighbor” may indicate the positions of pixels located adjacent to the target pixel within a certain unit of a frame or kernel. The “target kernel” including the target pixel may indicate a target object. Whether the target object is a defective pixel may be determined. The target neighbor pixels may correspond to a plurality of neighbor pixels other than a target pixel channel that is a target object to be corrected. The reference neighbor pixels may correspond to pixels excluding the reference pixel channel among the neighbor pixels each having the same color as the target pixel.

The defective pixel determiner 250 may compare the pixel data of the target pixel with the pixel data of the corrected reference pixel. In addition, the defective pixel determiner 250 may compare a threshold value with a difference value obtained by comparing the pixel data of the target pixel with the pixel data of the corrected reference pixel, and may determine whether the target pixel is a defective pixel. For example, when a difference between a threshold value included in threshold value information and the above-described difference value is greater than or equal to a preset difference value, the defective pixel determiner 250 may determine the target pixel to be a defective pixel. A detailed description of the process of determining the defective pixel will be described later with reference to FIGS. 5 and 6.

The defective pixel determiner 250 may generate defective pixel information (DPD) including both pixel data of the target pixel and coordinate information of the target pixel when the target pixel is determined to be a defective pixel. In one embodiment, the defective pixel information (DPD) may include information indicating whether the defective pixel is a defective pixel included in a target kernel serving as a flat kernel or a defective pixel included in a target kernel serving as a pattern kernel.

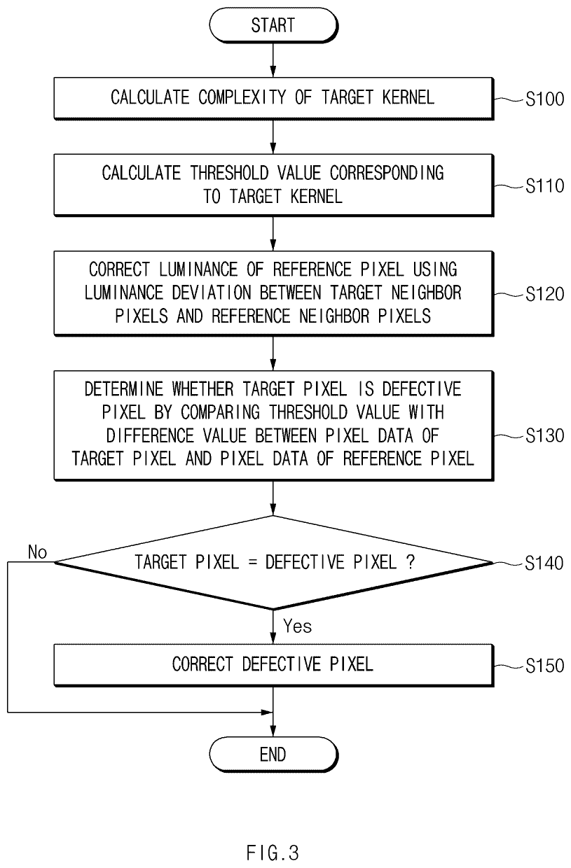

FIG. 3 is a flowchart illustrating operations of the image signal processor (ISP) when a target kernel is a pattern kernel based on some embodiments of the present disclosure.

Referring to FIGS. 2 and 3, when the target kernel is determined to be a pattern kernel by the kernel type determiner 220, the complexity calculator 230 may calculate the complexity of the target kernel serving as a pattern kernel (S100). For example, the complexity calculator 230 may determine, as the complexity of the target kernel, a standard deviation of pixel data of each pixel that is included in the same pattern as the target pixel, corresponds to a color filter of the same color as the target pixel, and/or is located at the same channel as the target pixel.

The threshold calculator 240 may calculate a threshold value corresponding to the target kernel based on the complexity of the target kernel (S110). In some embodiments, as the complexity of the target kernel increases, the threshold value can also increase. For example, the threshold calculator 240 may set the threshold value to ‘10’ when the complexity of the target kernel is ‘5’, and may set the threshold value to ‘20’ when the complexity of the target kernel is ‘10’. In one embodiment, when the target kernel is determined to be a pattern kernel, the threshold calculator 240 may calculate a threshold value based on pixel data of each pixel that is included in the same pattern as the target pixel, corresponds to a color filter of the same color as the target pixel, and/or is located at the same channel as the target pixel.

The defective pixel determiner 250 may determine whether the target pixel is a defective pixel based on the threshold value. The defective pixel determiner 250 may determine a target pixel group including the target pixel within the target kernel and a reference pixel group including a reference pixel to be compared with the target pixel.

When the target pixel is included in the pattern kernel, the defective pixel determiner 250 may correct luminance of the reference pixel using a luminance deviation between the target neighbor pixels and the reference neighbor pixels (S120). In addition, the defective pixel determiner 250 may compare pixel data of the target pixel with pixel data of the corrected reference pixel. In addition, the defective pixel determiner 250 may compare a threshold value with a difference value between pixel data of the target pixel and pixel data of the corrected reference pixel, and may determine whether the target pixel is a defective pixel (S130). For example, in a situation where the target pixel is included in the pattern kernel, when a difference value between pixel data of the target pixel and pixel data of the corrected reference pixel is greater than the threshold value, the defective pixel determiner 250 may determine the target pixel as a defective pixel.

When it is determined that the target pixel is not a defective pixel (No in S140), the image signal processor (ISP) 100 may determine that separate defective pixel correction is not necessary and may finish the process. When it is determined that the target pixel is a defective pixel (Yes in S140), the defective pixel corrector 300 may interpolate the target pixel (S150). The defective pixel corrector 300 may generate corrected image data (IDATA_P) including pixel data of the interpolated target pixel.

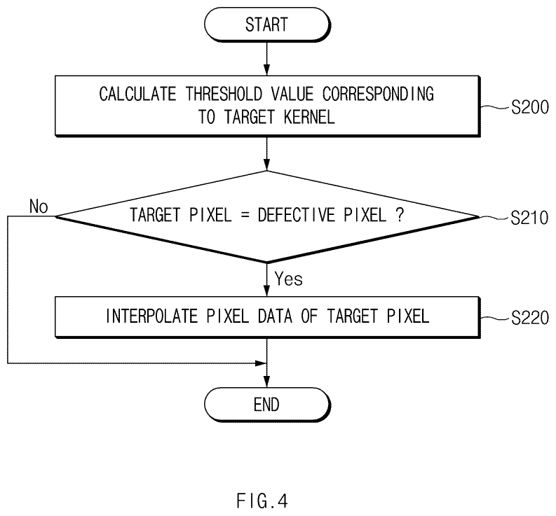

FIG. 4 is a flowchart illustrating operations of the image signal processor (ISP) 100 when the target kernel is a flat kernel based on some embodiments of the present disclosure.

Referring to FIGS. 2 and 4, when the target kernel is determined to be a flat kernel by the kernel type determiner 220, the threshold calculator 240 may calculate a threshold value corresponding to the target kernel (S200). In one embodiment, the threshold calculator 240 may calculate a threshold value based on pixel data of each pixel that corresponds to a color filter of the same color as the target pixel and/or is located at the same channel as the target pixel. For example, the threshold calculator 240 may determine, as a threshold value, a specific value corresponding to a standard deviation of pixel data of each pixel that corresponds to a color filter of the same color as the target pixel and/or is located at the same channel as the target pixel.

The defective pixel determiner 250 may determine whether the target pixel is a defective pixel based on the threshold value (S210). When a difference value between pixel data of the target pixel and an average value of pixel data of the respective reference pixels is greater than the threshold value, the defective pixel determiner 250 may determine the target pixel as a defective pixel. For example, when a difference value between pixel data of the target pixel and the average value of pixel data of the respective reference pixels that correspond to a color filter of the same color as the target pixel and/or are located at the same channel as the target pixel is greater than the threshold value, the defective pixel determiner 250 may determine the target pixel as a defective pixel.

When it is determined that the target pixel is not a defective pixel (No in S210), the image signal processor (ISP) 100 may determine that separate defective pixel correction is not necessary, and may finish the process.

When it is determined that the target pixel is a defective pixel (Yes in S210), the defective pixel corrector 300 may interpolate pixel data of the target pixel using pixel data of pixels included in the target kernel (S220). In one embodiment, the defective pixel corrector 300 may interpolate pixel data of the target pixel, based on pixel data of adjacent pixels that contact the target pixel, pixel data of pixels having the same attributes as the target pixel, and pixel data of each of pixels having the same attributes as the adjacent pixels. The defective pixel corrector 300 may interpolate the pixel data of the target pixel and may generate corrected image data (IDATA_P) including the interpolated pixel data of the target pixel.

FIG. 5 is a diagram illustrating a target kernel 500 according to an embodiment of the present disclosure. The embodiment of FIG. 5 may represent an example case where a target pixel is a green (G) color filter.

Referring to FIG. 5, the target kernel 500 may be processed by the image signal processor (ISP) 100 of FIG. 1, which includes an A4C (all 4-coupled) type sensor. The A4C sensor may detect a phase difference while acquiring a color image from all pixels. The A4C sensor may share one microlens with pixels arranged in a (2×2) matrix. The operations of the image signal processor (ISP) 100 according to the present disclosure may be performed based on a pixel array corresponding to a color filter array having a (Q×Q) Bayer pattern in which pixels having the same color filters are arranged in a (4×4) matrix. In the present disclosure, the A4C sensor may include a pixel array corresponding to a color filter array of a (Q×Q) Bayer pattern. Pixels arranged in a (4×4) matrix structure may constitute one unit pixel group, and four microlenses may correspond to one unit pixel group. In some embodiments, the target kernel may include a target pixel which includes pixels arranged in an (N×N) matrix including N rows and N columns, where N is an integer of 4 or greater.

In one embodiment, one microlens may correspond to pixels arranged in a (2×2) matrix structure. Four microlenses may be arranged in a (2×2) matrix structure, and may correspond to one unit pixel group. In one embodiment, the four microlenses may be arranged spaced apart from each other by the same distance from the center point of the pixel array arranged in a (4×4) matrix structure. For example, one microlens may be arranged to correspond to each of an upper left end, an upper right end, a lower left end, and a lower right end of the unit pixel group, so that four microlenses may be arranged in a (2×2) matrix structure.

One unit pixel group of the pixel array may correspond to a red (R) color filter, a green (G) color filter, or a blue (B) color filter, and four unit pixel groups may form a Bayer pattern. For example, the pixel array may form one unit pixel group of pixels arranged in a (4×4) matrix structure. In this embodiment, one unit pixel group may include pixels arranged in the (4×4) matrix structure including the red (R) color filters, the green (G) color filters, and/or the blue (B) color filters. The pixels arranged in the (4×4) matrix structure may be configured such that four pixels arranged in the (2×2) matrix structure share one microlens with each other. That is, the pixel array may be configured such that four microlenses are assigned to each unit pixel group divided into color filters.

The target kernel 500 may include a target pixel corresponding to a green (G) color filter. In the present disclosure, the defective pixel correction operation of the defective pixel detector 200 is performed in units of an (8×8) kernel having 8 rows and 8 columns. Depending on the performance of the image signal processor (ISP) 100, the required correction accuracy, the arrangement of color pixels, etc., kernels of different sizes may also be used, and the unit of such kernel is not limited thereto.

Pixels included in the target kernel 500 may be configured such that some pixels that correspond to the same color filter and are adjacent to each other, are grouped as shown in the pixel group array 510. For example, four green pixels (i.e., G00 pixel, G01 pixel, G10 pixel, and G11 pixel) that correspond to the green color filter and are adjacent to each other may be grouped into a pixel group (GGP00). Four pixels (G00, G01, G10, G11) within the GGP00 pixel group (GGP00) may share one microlens with each other. For example, four red pixels (i.e., R02 pixel, R03 pixel, R12 pixel, and R13 pixel) that correspond to the red color filter and are adjacent to each other may be grouped into a pixel group (RGP01). Four pixels (R02, R03, R12, R13) within the RGP01 pixel group (RGP01) may share one microlens with each other. For example, four blue pixels (i.e., B20 pixel, B21 pixel, B30 pixel, and B31 pixel) that correspond to the blue color filter and are adjacent to each other may be grouped into a pixel group (BGP10). Four pixels (B20, B21, B30, B31) within the BGP10 pixel group (BGP10) may share one microlens with each other. It may be understood that the remaining pixels included in the target kernel 500 are also grouped in the same manner as described above.

The image signal processor (ISP) 100 may determine, as a target kernel 500, a smallest square-shaped kernel including the G00 pixel (G00), the G07 pixel (G07), the G70 pixel (G70), and the G77 pixel (G77). In one embodiment, the target pixel (G22) arranged in the edge region of a (Q×Q) pattern within the target kernel 500 is a target pixel. The defective pixel determiner 250 may determine a GGP00 pixel group (GGP00), a GGP03 pixel group (GGP03), a GGP12 pixel group (GGP12), a GGP21 pixel group (GGP21), a GGP22 pixel group (GGP22), a GGP30 pixel group (GGP30), and a GGP33 pixel group (GGP33) that have the same color as the GGP11 pixel group (GGP11) including the target pixel (G22), to be comparison target groups to be compared with the GGP11 pixel group (GGP11) including the target pixel.

In the present disclosure, the same channel may refer to the position of a pixel corresponding to the same phase with respect to the position of a microlens. In the arrangement structure of four pixels arranged in a (2×2) matrix structure sharing the same microlens, a position of an upper left side (e.g., a position of the target pixel) may be defined as a first channel, a position of an upper right side may be defined as a second channel, a position of a lower left side may be defined as a third channel, and a position of a lower right side may be defined as a fourth channel.

For example, in the target kernel 500, reference pixels corresponding to the same first channel as the target pixel (G22) may correspond to the G00 pixel of the GGP00 pixel group (GGP00), the G06 pixel of the GGP03 pixel group (GGP03), the G24 pixel of the GGP12 pixel group (GGP12), the G42 pixel of the GGP21 pixel group (GGP21), the G44 pixel of the GGP22 pixel group (GGP22), the G60 pixel of the GGP30 pixel group (GGP30), and the G66 pixel of the GGP33 pixel group (GGP33).

Reference neighbor pixels corresponding to the second, third and fourth channels that are the same as the target neighbor pixels (G23, G32, G33) may correspond to the G01, G10, and G11 pixels of the GGP00 pixel group (GGP00), may correspond to the G07, G16, and G17 pixels of the GGP03 pixel group (GGP03), may correspond to the G25, G34, and G35 pixels of the GGP12 pixel group (GGP12), may correspond to the G43, G54, and G55 pixels of the GGP22 pixel group (GGP22), may correspond to the G61, G70, and G71 pixels of the GGP30 pixel group (GGP30), and may correspond to the G67, G76, and G77 pixels of the GGP33 pixel group (GGP33).

Accordingly, the defective pixel determiner 250 may calculate a luminance deviation between pixel data of the target neighbor pixels (G23, G32, G33) and pixel data of each of the reference neighbor pixels (G01, G10, G11/G07, G16, G17/G25, G34, G35/G43, G52, G53/G45, G54, G55/G61, G70, G71/G67, G76, G77) of the reference pixels (G00, G06, G24, G42, G44, G60, G66) that correspond to the same color filter as the target pixel within each pixel group or are located at the same channel as the target pixel within each pixel group. The defective pixel determiner 250 may correct the luminance of the reference pixels (G00, G06, G24, G42, G44, G60, G66) using the calculated luminance deviation.

A method for calculating the luminance deviation by the defective pixel determiner 250 will be described with reference to Equations 1 to 7 below.

$$diff\_G 00 \_G 22 = ( G 01 + G 10 + G 11 ) / 3 - ( G 23 + G 32 + G 33 ) / 3 \qquad Equation 1$$

As shown in Equation 1, a luminance deviation (diff_G00_G22) between the reference pixel (G00) and the target pixel (G22) may be obtained by subtracting a second average value obtained by averaging pixel data of the target neighbor pixels (G23, G32, G33) (i.e., by dividing the sum of three pixel data values by 3) from a first average value obtained by averaging pixel data of the reference neighbor pixels (G01, G10, G11) (i.e. by dividing the sum of three pixel data values by 3).

$$diff\_G 06 \_G 22 = ( G 07 + G 16 + G 17 ) / 3 - ( G 23 + G 32 + G 33 ) / 3 \qquad Equation 2$$

As shown in Equation 2, a luminance deviation (diff_G06_G22) between the reference pixel (G06) and the target pixel (G22) may be obtained by subtracting a second average value obtained by averaging pixel data of the target neighbor pixels (G23, G32, G33) (i.e., by dividing the sum of three pixel data values by 3) from a third average value obtained by averaging pixel data of the reference neighbor pixels (G07, G16, G17) (i.e. by dividing the sum of three pixel data values by 3).

$$diff\_G 24 \_G 22 = ( G 25 + G 34 + G 35 ) / 3 - ( G 23 + G 32 + G 33 ) / 3 \qquad Equation 3$$

As shown in Equation 3, a luminance deviation (diff_G24_G22) between the reference pixel (G24) and the target pixel (G22) may be obtained by subtracting a second average value obtained by averaging pixel data of the target neighbor pixels (G23, G32, G33) (i.e., by dividing the sum of three pixel data values by 3) from a fourth average value obtained by averaging pixel data of the reference neighbor pixels (G25, G34, G35) (i.e. by dividing the sum of three pixel data values by 3).

$$diff\_G 42 \_G 22 = ( G 43 + G 52 + G 53 ) / 3 - ( G 23 + G 32 + G 33 ) / 3 \qquad Equation 4$$

As shown in Equation 4, a luminance deviation (diff_G42_G22) between the reference pixel (G42) and the target pixel (G22) may be obtained by subtracting a second average value obtained by averaging pixel data of the target neighbor pixels (G23, G32, G33) (i.e., by dividing the sum of three pixel data values by 3) from a fifth average value obtained by averaging pixel data of the reference neighbor pixels (G43, G52, G53) (i.e. by dividing the sum of three pixel data values by 3).

$$diff\_G 44 \_G 22 = ( G 45 + G 54 + G 55 ) / 3 - ( G 23 + G 32 + G 33 ) / 3 \qquad Equation 5$$

As shown in Equation 5, a luminance deviation (diff_G44_G22) between the reference pixel (G44) and the target pixel (G22) may be obtained by subtracting a second average value obtained by averaging pixel data of the target neighbor pixels (G23, G32, G33) (i.e., by dividing the sum of three pixel data values by 3) from a sixth average value obtained by averaging pixel data of the reference neighbor pixels (G45, G54, G55) (i.e. by dividing the sum of three pixel data values by 3).

$$diff\_G 60 \_G 22 = ( G 61 + G 70 + G 71 ) / 3 - ( G 23 + G 32 + G 33 ) / 3 \qquad Equation 6$$

As shown in Equation 6, a luminance deviation (diff_G60_G22) between the reference pixel (G60) and the target pixel (G22) may be obtained by subtracting a second average value obtained by averaging pixel data of the target neighbor pixels (G23, G32, G33) (i.e., by dividing the sum of three pixel data values by 3) from a seventh average value obtained by averaging pixel data of the reference neighbor pixels (G61, G70, G71) (i.e. by dividing the sum of three pixel data values by 3).

$$diff\_G 66 \_G 22 = ( G 67 + G 76 + G 77 ) / 3 - ( G 23 + G 32 + G 33 ) / 3 \qquad Equation 7$$

As shown in Equation 7, a luminance deviation (diff_G66_G22) between the reference pixel (G66) and the target pixel (G22) may be obtained by subtracting a second average value obtained by averaging pixel data of the target neighbor pixels (G23, G32, G33) (i.e., by dividing the sum of three pixel data values by 3) from an eighth average value obtained by averaging pixel data of the reference neighbor pixels (G67, G76, G77) (i.e. by dividing the sum of three pixel data values by 3).

In addition, the defective pixel determiner 250 may correct luminance of the reference pixels (G00, G06, G24, G42, G44, G60, G66) using the luminance deviation obtained by Equations 1 to 7, and may obtain pixel data (hereinafter referred to as “correction data”) of the corrected reference pixel. A method for obtaining correction data by the defective pixel determiner 250 will be described with reference to Equations 8 to 14 below.

$$G 00 \_refine = G 00 - diff\_G 00 \_G 22 \qquad Equation 8$$

As shown in Equation 8, correction data (G00_refine) of the reference pixel (G00) may be obtained by subtracting a luminance deviation (diff_G00_G22) between the reference pixel (G00) and the target pixel (G22) from pixel data of the reference pixel (G00).

$$G 06 \_refine = G 06 - diff\_G 06 \_G 22 \qquad Equation 9$$

As shown in Equation 9, correction data (G06_refine) of the reference pixel (G06) may be obtained by subtracting a luminance deviation (diff_G06_G22) between the reference pixel (G06) and the target pixel (G22) from pixel data of the reference pixel (G06).

$$G 24 \_refine = G 24 - diff\_G 24 \_G 22 \qquad Equation 10$$

As shown in Equation 10, correction data (G24_refine) of the reference pixel (G24) may be obtained by subtracting a luminance deviation (diff_G24_G22) between the reference pixel (G24) and the target pixel (G22) from pixel data of the reference pixel (G24).

$$G 42 \_refine = G 42 - diff\_G 42 \_G 22 \qquad Equation 11$$

As shown in Equation 11, correction data (G42_refine) of the reference pixel (G42) may be obtained by subtracting a luminance deviation (diff_G42_G22) between the reference pixel (G42) and the target pixel (G22) from pixel data of the reference pixel (G42).

$$G 44 \_refine = G 44 - diff\_G 44 \_G 22 \qquad Equation 12$$

As shown in Equation 12, correction data (G44_refine) of the reference pixel (G44) may be obtained by subtracting a luminance deviation (diff_G44_G22) between the reference pixel (G44) and the target pixel (G22) from pixel data of the reference pixel (G44).

$$G 60 \_refine = G 60 - diff\_G 60 \_G 22 \qquad Equation 13$$

As shown in Equation 13, correction data (G60_refine) of the reference pixel (G60) may be obtained by subtracting a luminance deviation (diff_G60_G22) between the reference pixel (G60) and the target pixel (G22) from pixel data of the reference pixel (G60).

$$G 66 \_refine = G 66 - diff\_G 66 \_G 22 \qquad Equation 14$$

As shown in Equation 14, correction data (G66_refine) of the reference pixel (G66) may be obtained by subtracting a luminance deviation (diff_G66_G22) between the reference pixel (G66) and the target pixel (G22) from pixel data of the reference pixel (G66).

In some embodiments, the defective pixel determiner 250 may compare the pixel data of the target pixel with the pixel data of the corrected reference pixels (G00, G06, G24, G42, G44, G60, G66). In addition, the defective pixel determiner 250 may compare a threshold value with a difference value obtained by comparing the pixel data of the target pixel (G22) with the pixel data of the corrected reference pixel, and may determine whether the target pixel (G22) is a defective pixel based on the result of such comparison.

A method for determining a defective pixel by the defective pixel determiner 250 will be described with reference to Equations 15 to 21 below.

$$abs\_G 22 \_G 00 = abs ( G 22 - G 00 \_refine ) > dp\_threshold \qquad Equation 15$$

In Equation 15, “abs” may represent an absolute value. The defective pixel determiner 250 may compare the pixel data of the target pixel (G22) with the correction data (G00_refine) of the reference pixel (G00), and may determine the target pixel (G22) as a defective pixel when a difference value (absolute value) in pixel data between the target pixel (G22) and the reference pixel (G00) is greater than a threshold value (dp_threshold).

$$abs\_G 22 \_G 06 = abs ( G 22 - G 06 \_refine ) > dp\_threshold \qquad Equation 16$$

In Equation 16, the defective pixel determiner 250 may compare the pixel data of the target pixel (G22) with the correction data (G6_refine) of the reference pixel (G06), and may determine the target pixel (G22) as a defective pixel when a difference value (absolute value) in pixel data between the target pixel (G22) and the reference pixel (G06) is greater than a threshold value (dp_threshold).

$$abs\_G 22 \_G 24 = abs ( G 22 - G 240 \_refine ) > dp\_threshold \qquad Equation 17$$

In Equation 17, the defective pixel determiner 250 may compare the pixel data of the target pixel (G22) with the correction data (G24_refine) of the reference pixel (G24), and may determine the target pixel (G22) as a defective pixel when a difference value (absolute value) in pixel data between the target pixel (G22) and the reference pixel (G24) is greater than a threshold value (dp_threshold).

$$abs\_G 22 \_G 42 = abs ( G 22 - G 42 \_refine ) > dp\_threshold \qquad Equation 18$$

In Equation 18, the defective pixel determiner 250 may compare the pixel data of the target pixel (G22) with the correction data (G42_refine) of the reference pixel (G42), and may determine the target pixel (G22) as a defective pixel when a difference value (absolute value) in pixel data between the target pixel (G22) and the reference pixel (G42) is greater than a threshold value (dp_threshold).

$$abs\_G 22 \_G 44 = abs ( G 22 - G 44 \_refine ) > dp\_threshold \qquad Equation 19$$

In Equation 19, the defective pixel determiner 250 may compare the pixel data of the target pixel (G22) with the correction data (G44_refine) of the reference pixel (G44), and may determine the target pixel (G22) as a defective pixel when a difference value (absolute value) in pixel data between the target pixel (G22) and the reference pixel (G44) is greater than a threshold value (dp_threshold).

$$abs\_G 22 \_G 60 = abs ( G 22 - G 60 \_refine ) > dp\_threshold \qquad Equation 20$$

In Equation 20, the defective pixel determiner 250 may compare the pixel data of the target pixel (G22) with the correction data (G60_refine) of the reference pixel (G60), and may determine the target pixel (G22) as a defective pixel when a difference value (absolute value) in pixel data between the target pixel (G22) and the reference pixel (G60) is greater than a threshold value (dp_threshold).

$$abs\_G 22 \_G 66 = abs ( G 22 - G 66 \_refine ) > dp\_threshold \qquad Equation 21$$

In Equation 21, the defective pixel determiner 250 may compare the pixel data of the target pixel (G22) with the correction data (G66_refine) of the reference pixel (G66), and may determine the target pixel (G22) as a defective pixel when a difference value (absolute value) in pixel data between the target pixel (G22) and the reference pixel (G66) is greater than a threshold value (dp_threshold).

FIG. 6 is a diagram illustrating a target kernel 600 according to another embodiment of the present disclosure. The embodiment of FIG. 6 may represent an example case where a target pixel is a color pixel (e.g., a blue (B) color filter).

Referring to FIG. 6, pixels included in the target kernel 600 may be configured such that some pixels that correspond to the same color filter and are adjacent to each other are grouped as shown in the pixel group array 610. For example, four red pixels (i.e., R00 pixel, R01 pixel, R10 pixel, and R11 pixel) that correspond to the red color filter and are adjacent to each other may be grouped into a pixel group (RGP00). Four pixels (R00, R01, R10, R11) within the RGP00 pixel group (RGP00) may share one microlens with each other. For example, four green pixels (i.e., G02 pixel, G03 pixel, G12 pixel, and G13 pixel) that correspond to the green color filter and are adjacent to each other may be grouped into a pixel group (GGP01). Four pixels (G02, G03, G12, G13) within the GGP01 pixel group (GGP01) may share one microlens with each other. For example, four blue pixels (i.e., B22 pixel, B23 pixel, B32 pixel, and B33 pixel) that correspond to the blue color filter and are adjacent to each other may be grouped into a pixel group (BGP11). Four pixels (B22, B23, B32, B33) within the BGP11 pixel group (BGP11) may share one microlens with each other. The remaining pixels included in the target kernel 600 are also grouped in the same manner as described above.

The image signal processor (ISP) 100 may determine, as the target kernel 600, a smallest square-shaped kernel including the R00 pixel (R00), the R07 pixel (R07), the R70 pixel (R70), and the R77 pixel (R77). In one embodiment, the B22 pixel (B22) arranged in the edge region of the target kernel 600 is a target pixel. The defective pixel determiner 250 may determine a BGP12 pixel group (BGP12), a BGP21 pixel group (BGP21), and a BGP22 pixel group (BGP22) that have the same color as the BGP11 pixel group (BGP11) including the target pixel to be comparison target groups to be compared with the BGP11 pixel group (BGP11) including the target pixel.

In the target kernel 600, reference pixels located in the same first channel as the target pixel (B22) may correspond to a B24 pixel of the BGP12 pixel group (BGP12), a B42 pixel of the BGP21 pixel group (BGP21), and a B44 pixel of the BGP22 pixel group (BGP22).

Reference neighbor pixels located in the same second to fourth channels as the target neighbor pixels (B23, B32, B33) may correspond to pixels (B25, B34, B35) of the BGP12 pixel group (BGP12), pixels (B43, B52, B53) of the BGP21 pixel group (BGP21), and pixels (B45, B54, B55) of the BGP22 pixel group (BGP22).

Accordingly, the defective pixel determiner 250 may calculate a luminance deviation between pixel data of the target neighbor pixels (B23, B32, B33) and pixel data of the reference neighbor pixels (B25, B34, B35/B43, B52, B53/B45, B54, B55) of the reference pixels (B24, B42, B44) that correspond to the same color filter as the target pixel within each pixel group or are located at the same channel as the target pixel within each pixel group. The defective pixel determiner 250 may correct the luminance of the reference pixels (B24, B42, B44) using the calculated luminance deviation.

Then, the defective pixel determiner 250 may obtain pixel data (correction data) of the corrected reference pixel. The defective pixel determiner 250 may compare a threshold value with a difference value obtained by comparing the pixel data of the target pixel with the correction data, and may determine whether the target pixel (B22) is a defective pixel. A method for detecting a defective pixel when a target pixel is a blue (B) color pixel is similar to the method of FIG. 5, and as such redundant description thereof will herein be omitted for brevity. A method for detecting a defective pixel when a target pixel is a red (R) color pixel is also similar to the method of FIG. 5, and as such redundant description thereof will herein be omitted for brevity.

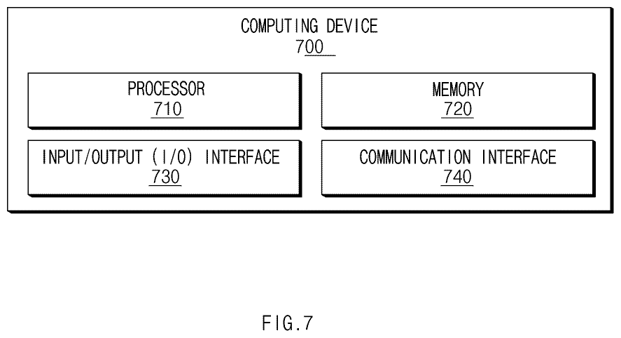

FIG. 7 is a block diagram showing a computing device 700 corresponding to the image signal processor of FIG. 1.

Referring to FIG. 7, the computing device 700 may represent an embodiment of a hardware configuration for performing the operation of the image signal processor 100 of FIG. 1.

The computing device 700 may be mounted on a chip that is independent from the chip on which the image sensing device is mounted. According to an embodiment, the chip on which the image sensing device is mounted and the chip on which the computing device 700 is mounted may be implemented in one package, for example, a multi-chip package (MCP), but the scope of the present disclosure is not limited thereto.

Additionally, the internal configuration or arrangement of the image sensing device and the image signal processor 100 described in FIG. 1 may vary depending on the embodiment. For example, at least a portion of the image sensing device may be included in the image signal processor 100. Alternatively, at least a portion of the computing device 700 may be included in the image sensing device. In this case, at least a portion of the computing device 700 may be mounted together on a chip on which the image sensing device is mounted.

The computing device 700 may include a processor 710, a memory 720, an input and output input/output (I/O) interface 730, and a communication interface 740.

The processor 710 may process data and/or instructions required to perform the operations of the components (200, 300) of the image signal processor 100 described in FIG. 1. That is, the processor 710 may refer to the image signal processor 100, but the scope of the present disclosure is not limited thereto.

The memory 720 may store data and/or instructions required to perform operations of the components (200, 300) of the image signal processor 100, and may be accessed by the processor 710. For example, the memory 720 may be volatile memory (e.g., Dynamic Random Access Memory (DRAM), Static Random Access Memory (SRAM), etc.) or non-volatile memory (e.g., Programmable Read Only Memory (PROM), Erasable PROM (EPROM), EEPROM (Electrically Erasable PROM), flash memory, etc.).

That is, the computer program for performing the operations of the image signal processor 100 disclosed in the present disclosure is recorded in the memory 720 and executed and processed by the processor 710, thereby implementing the operations of the image signal processor 100.

The input/output interface 730 connects an external input device (e.g., keyboard, mouse, touch panel, etc.) and/or an external output device (e.g., display) to the processor 710 to allow data to be transmitted and received therebetween.

The communication interface 740 can transmit and receive various data with an external device (e.g., an application processor, external memory, etc.), and may be a device that supports wired or wireless communication.

As is apparent from the above description, the image signal processor according to the embodiments of the present disclosure can more correctly detect the defective pixels in the edge region of an image.

The embodiments of the present disclosure may provide a variety of advantageous effects capable of being directly or indirectly recognized.

Although a number of illustrative embodiments have been described, it should be understood that modifications and enhancements to the disclosed embodiments and other embodiments can be devised based on what is described and/or illustrated in the present disclosure. Furthermore, the embodiments may be combined to form additional embodiments.

What is claimed is:

1. An image signal processor comprising:
a defective pixel detector configured to determine whether a target pixel is a defective pixel based on pixel data of a reference pixel having the same attributes as the target pixel; and
a defective pixel corrector configured to correct pixel data of the target pixel when it is determined that the target pixel is the defective pixel,
wherein the defective pixel detector is configured to:
correct a luminance of the reference pixel using a luminance deviation between target neighbor pixels adjacent to the target pixel and reference neighbor pixels adjacent to the reference pixel;
compare a threshold value with a difference value obtained based on the pixel data of the target pixel and correction data of the reference pixel; and
determine whether the target pixel is the defective pixel based on a result of the comparison.

2. The image signal processor according to claim 1, wherein:
the reference pixel having the same attributes as the target pixel includes a color filter having the same color as a color filter corresponding to the target pixel, and is located at the same channel as the target pixel.

3. The image signal processor according to claim 1, wherein the defective pixel detector includes:
a kernel type determiner configured to determine whether the target kernel is a flat kernel or a pattern kernel by analyzing a texture of the target kernel;
a complexity calculator configured to calculate complexity for the target kernel;
a threshold calculator configured to calculate the threshold value for the target pixel based on kernel type information of the kernel type determiner and the calculated complexity; and
a defective pixel determiner configured to compare the difference value with the threshold value to determine whether the target pixel is the defective pixel.

4. The image signal processor according to claim 3, wherein:
the complexity corresponds to an average deviation of pixels included in the target kernel.

5. The image signal processor according to claim 3, wherein the threshold calculator is configured to:
when it is determined that the target kernel is the flat kernel, calculate the threshold value based on pixel data of each pixel that corresponds to a color filter having the same color as the target pixel and is located at the same channel as the target pixel; and
when it is determined that the target kernel is the pattern kernel, calculate the threshold value based on pixel data of each pixel that is included in the same pattern as the target pixel, corresponds to a color filter having the same color as the target pixel, and is located at the same channel as the target pixel.

6. The image signal processor according to claim 3, wherein the threshold calculator is configured to:
when the target kernel is the pattern kernel, determine the threshold value to be greater than a value of the complexity.

7. The image signal processor according to claim 3, wherein the defective pixel determiner is configured to:
when it is determined that the target kernel is the pattern kernel, correct the luminance of the reference pixel using the luminance deviation.

8. The image signal processor according to claim 3, wherein the defective pixel determiner is configured to:
when it is determined that the target kernel is the flat kernel, and when a difference value between pixel data of the target pixel and an average value of pixel data of the reference pixels is greater than the threshold value,
determine the target pixel as the defective pixel.

9. The image signal processor according to claim 3, wherein the defective pixel determiner is configured to:
when the difference value is greater than or equal to the threshold value, determine the target pixel as the defective pixel.

10. The image signal processor according to claim 1, wherein:
the target pixel and the target neighbor pixels are configured to share a microlens.

11. The image signal processor according to claim 1, wherein:
the reference pixel and the reference neighbor pixels are configured to share a microlens.

12. The image signal processor according to claim 1, wherein:
a target kernel including the target pixel is configured such that four microlenses correspond to a unit pixel group.

13. The image signal processor according to claim 1, wherein:
a target kernel including the target pixel includes pixels arranged in an (N×N) matrix including N rows and N columns,
wherein N is an integer of 4 or greater.

14. An image signal processor comprising:
a threshold calculator configured to calculate a threshold value for a target pixel included in a target kernel based on kernel type information and complexity of the target kernel; and
a defective pixel determiner configured to determine whether the target pixel is a defective pixel based on pixel data of a reference pixel having the same attributes as the target pixel,
wherein the defective pixel determiner is configured to:
correct a luminance of the reference pixel using a luminance deviation between target neighbor pixels adjacent to the target pixel and reference neighbor pixels adjacent to the reference pixel;
compare the threshold value with a difference value obtained based on the pixel data of the target pixel and correction data of the reference pixel; and
determine whether the target pixel is the defective pixel based on a result of the comparison.

15. The image signal processor according to claim 14, wherein:
the reference pixel having the same attributes as the target pixel includes a color filter having the same color as a color filter corresponding to the target pixel, and is located at the same channel as the target pixel.

16. The image signal processor according to claim 14, wherein:
the complexity corresponds to an average deviation of pixels included in the target kernel.

17. The image signal processor according to claim 14, wherein the threshold calculator is configured to:
when it is determined that the target kernel is the flat kernel based on the kernel type information, calculate the threshold value based on pixel data of each pixel that corresponds to a color filter having the same color as the target pixel and is located at the same channel as the target pixel; and
when it is determined that the target kernel is the pattern kernel based on the kernel type information, calculate the threshold value based on pixel data of each pixel that is included in the same pattern as the target pixel, corresponds to a color filter having the same color as the target pixel, and is located at the same channel as the target pixel.

18. The image signal processor according to claim 14, wherein the target kernel includes:
pixels arranged in an (N×N) matrix including N rows and N columns,
wherein N is an integer of 4 or greater.

19. The image signal processor according to claim 18, wherein:
the pixels arranged in the (N×N) matrix are grouped into pixel groups arranged in an (M×M) matrix, where M is an integer of 2 or greater;
wherein
a first pixel group from among the pixel groups includes the target pixel and the target neighbor pixels; and
a second pixel group from among the pixel groups includes the reference pixel located in the same channel as the target pixel, and the reference neighbor pixels located in the same channel as the target neighbor pixels.

20. The image signal processor according to claim 19, wherein:
the target pixel and the target neighbor pixels are configured to share a microlens; and
the reference pixel and the reference neighbor pixels are configured to share a microlens.
